(19) United States
(12) Patent Application Publication
(10) Pub. No.: US 2010/0147580 A1
(43) Pub. Date: Jun. 17, 2010

(54) EXTENSION CORD ASSEMBLY

(76) Inventor: Jeffrey Koesterich, Teaneck, NJ (US)

Correspondence Address: L.C. BEGIN & ASSOCIATES, PLLC, 510 HIGHLAND AVENUE, PMB 403, MILFORD, MI, 48381, US

(21) Appl. No.: 12/577,782

(22) Filed: Oct. 13, 2009

Related U.S. Application Data
(60) Provisional application No. 61/138,175, filed on Dec. 17, 2008.

(51) Int. Cl. H05K 5/00

(52) U.S. Cl. 174/520

(57) ABSTRACT

One embodiment of an extension cord assembly includes a support structure, a support component, and an extension cord housing. The support structure may be rested on a surface and the extension cord housing may be carried by the support structure, while the support component may be coupled with a portion of an electrical appliance. Further, the extension cord housing may be adapted to retractably releasing an extension cord. The extension cord may be capable of electrically coupling an electrical appliance to a power source. Moreover, the extension cord may be positioned away from a ground surface upon electrically coupling the electrical appliance to the power source for avoiding a contact between the extension cord and articles resting on the ground surface and thereby enabling uninterrupted use of the extension cord.

### CROSS REFERENCE TO RELATED APPLICATION

This application claims the benefit of U.S. Provisional Application No. 61/138,175 filed on Dec. 17, 2008, the disclosure of which is incorporated by reference.

### FIELD OF THE DISCLOSURE

The present disclosure generally relates to electrical power extenders, and, more particularly to an extension cord assembly, which provides uninterrupted use of an extension cord.

### BACKGROUND OF THE DISCLOSURE

In many household activities, use of an extension cord to provide power to an electrical appliance is common. Generally, the extension cord may be used for providing power from a power source, such as a wall outlet, to an electrical appliance, which is distantly located from the power source. For example, the extension cord may be used for powering an electrical appliance, such as a lawn mower and a snow blower, which may be typically used for performing outdoor activities.

Generally, while performing such outdoor activities the extension cord may run over a ground surface. The use of extension cords in such a manner often creates problems. More specifically, the extension cord readily gets tangled up with articles, resting on the ground surface. Further, due to the tangling, the effective length of the extension cord gets shortened. Accordingly, an individual may required to invest considerable amount of time for untangling the extension cord, which may be a cumbersome and time-consuming task.

One typical example, when an individual may face problem while using an extension cord, may be when the individual performs yard work with the help of a lawn mower. Specifically, while performing yard work, it is quite common that the extension cord may be run over by the lawn mower, because the extension cord gets hidden in the grass. Therefore, the extension cord may get severed by the mower blades or even get caught in the mower blades.

### SUMMARY OF THE DISCLOSURE

One embodiment of an extension cord assembly for an electrical appliance may include a support structure. The support structure may be rested on a flat surface. The electrical appliance may further include an extension cord housing. The extension cord housing may be carried by the support structure. Further, the extension cord housing may be adapted to retractably releasing an extension cord. The extension cord may be capable of electrically coupling the electrical appliance to a power source. Moreover, the extension cord may be positioned above and away from a ground surface upon electrically coupling the electrical appliance to the power source for avoiding a contact between the extension cord and articles resting on the ground surface and thereby enabling uninterrupted use of the extension cord.

### BRIEF DESCRIPTION OF THE DRAWINGS

The advantages and features of the present disclosure will become better understood with reference to the following detailed description and claims taken in conjunction with the accompanying drawing, in which:

FIG. 1 is a perspective view of one embodiment of a support structure along with an extension cord assembly;

FIG. 2 is a perspective view of another embodiment of a support structure of the extension cord assembly of FIG. 1;

FIG. 3 is an exploded perspective view of a support component of the extension cord assembly of the FIG. 1;

FIG. 4 illustrates an environment in which the extension cord assembly of FIG. 1 is used in conjunction with an electrical appliance; and

FIG. 5 is a perspective view of another embodiment of an extension cord assembly.

Like reference numerals refer to like parts throughout the description of several views of the drawings.

### DETAILED DESCRIPTION OF THE DISCLOSURE

The exemplary embodiments described herein in detail for illustrative purposes are subject to many variations in structure and design. It should be emphasized, however, that the present disclosure is not limited to an extension cord assembly as shown and described. It is understood that various omissions and substitutions of equivalents are contemplated as circumstances may suggest or render expedient, but these are intended to cover the application or implementation without departing from the spirit or scope of the claims of the present disclosure. Also, it is to be understood that the phraseology and terminology used herein is for the purpose of description and should not be regarded as limiting.

The terms, “first,” “second,” and the like, herein do not denote any order, elevation or importance, but rather are used to distinguish one element with another. Further, the terms, “a” and “an” herein do not denote a limitation of quantity, but rather denote the presence of at least one of the referenced item.

The present disclosure may provide an extension cord assembly for an electrical appliance. The extension cord assembly may enable in using an electrical appliance, which is distantly located from a power source, such as a wall outlet. Further, the extension cord assembly may provide an uninterrupted use of an extension cord, which may be used in conjunction with the distantly located electrical appliance. More specifically, the extension cord assembly enables in holding the extension cord above and away from a ground surface for avoiding a contact between the extension cord and articles resting on the ground surface. Therefore, the extension cord may be saved from getting tangled up with the articles, and even with the electrical appliance, resting on the ground surface.

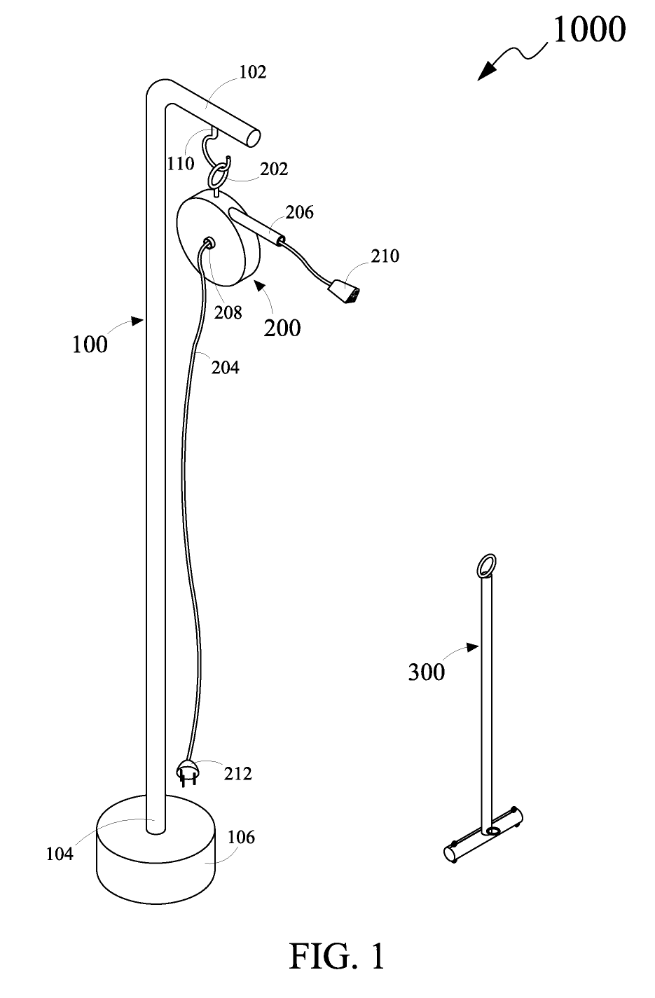

Referring to FIG. 1, there is shown one embodiment of an extension cord assembly 1000. The extension cord assembly 1000 may include a support structure 100. The support structure 100 may be a pole having an “inverted L-shaped structure.” Alternatively, the support structure 100 may be configured to have other shapes, such as an “I-shaped structure.” The support structure 100 may be adapted to be rested on a flat surface. More specifically, the support structure 100 includes an upper end portion 102 and a lower end portion 104. Further, the lower end portion 104 of the support structure 100 may be rested on the surface. The term “surface” used herein may be a ground surface, a floor or an elevated surface capable of supporting the support structure 100 thereon.

In the present embodiment, the support structure 100 may include a weighted base 106 configured at the lower end portion 104 of the support structure 100. The weighted base 106 may be adapted to be placed on a surface, such as the ground surface, for allowing the support structure 100 to rest on the ground surface. More specifically, the weighted base 106 may include a substantial weight, which may be capable of holding the support structure 100 in a vertically upward position on the ground surface.

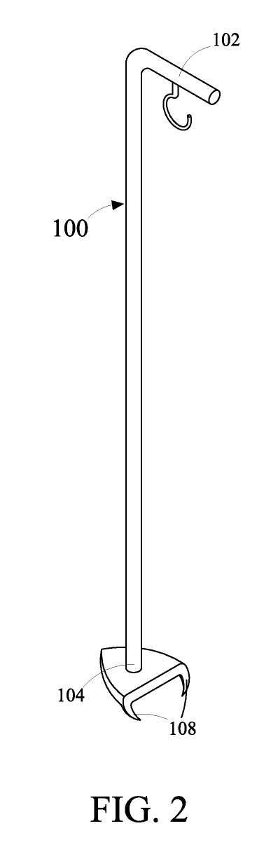

In another embodiment of the present disclosure, the support structure 100 may include a plurality of spikes 108 configured at the lower end portion 104 of the support structure 100, as shown FIG. 2. The support structure 100 includes the plurality of spikes 108 instead of the weighted base 106 (as shown in FIG. 1), for allowing the support structure 100 to rest securely on the ground surface. Specifically, the plurality of spikes 108 may be driven into the ground surface and thereby allowing the support structure 100 to rest in the vertically upward position on the ground surface. In yet another embodiment of the present disclosure, the support structure 100 may include a conical shaped lower end portion, which may be driven into the ground surface, for allowing the support structure 100 to rest securely on the ground surface.

Referring back to FIG. 1, the support structure 100 may further include a hook 110 configured on the upper end portion 102 of the support structure 100.

The extension cord assembly 1000 may further include an extension cord housing 200 that may be carried by the support structure 100. More specifically, the extension cord housing 200 may include a loop 202 configured thereon. The loop 202 may be received by the hook 110 for enabling the extension cord housing 200 to be carried by the support structure 100. Alternatively, the extension cord housing 200 may be carried by the support structure 100 by other arrangement, such as a nut-bolt arrangement, and a hook and loop fastener arrangement. Further, the hook 110 may be configured in carrying the extension cord housing 200 on the upper end portion 102 of the support structure 100 and away from the ground surface.

The extension cord housing 200 may be capable of retractably releasing an extension cord 204. More specifically, the extension cord housing 200 may include a spool (not shown) configured therewithin. The extension cord 204 may be wound inside the housing the spool. Further, the opposite ends of the extension cord 204 may be pulled out from the extension cord housing 200 through outlets 206 and 208 respectively. For example, one end of the extension cord 204, coupled to a female connector 210, may be pulled out through the outlet 206; and another end of the extension cord 204, coupled to a male connector 212, may be pulled through the outlet 208.

As explained herein, the extension cord housing 200 may be capable of retractably releasing the extension cord 204. Specifically, the extension cord housing 200 may include a retracting mechanism (not shown) capable of retracting the extension cord 204, after the extension cord is pulled out from the extension cord housing 200. For example, the extension cord housing 200 may be configured with a retracting mechanism, such as a spring-powered mechanism or a swivel mechanism, which is known in the art, and capable of retracting the extension cord 204 into the extension cord housing 200.

The extension cord 204 may be capable of electrically coupling an electrical appliance to a power source. More specifically, the male connector 212 of the extension cord 204 may be electrically coupled to the wall outlet, and the female connector 210 of the extension cord 204 may be electrically coupled to a power cord of the electrical appliance.

The extension cord assembly 1000 may further include a support component 300, which may be mounted on an electrical appliance. The support component 300 may be capable of supporting and suspending the power cord of the electrical appliance. More specifically, the support component 300 may support the power cord of the electrical appliance, when the power cord may be electrically coupled to the extension cord 204.

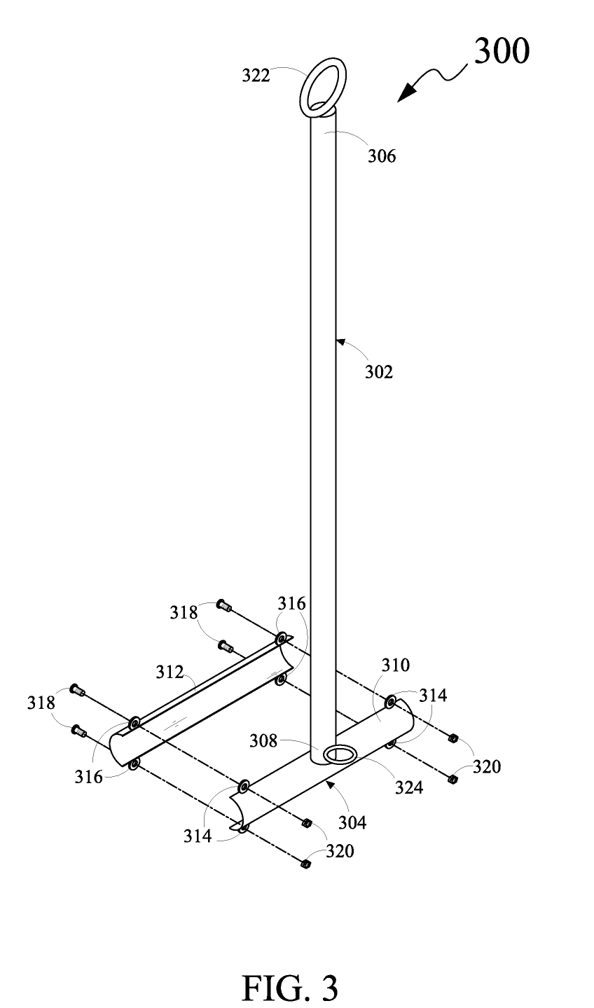

Referring to FIG. 3, an exploded perspective view of the support component 300 of the extension cord assembly 1000 is shown. The support component 300 may include a body member 302. The body member 302 may include a top end portion 306 and an opposite bottom end portion 308. Further, the support component 300 may include a base member 304 configured at an end portion of the body member 302. In one embodiment, the base member 304 may be configured at the bottom end portion 308 of the body member 302.

The base member 304 may be adapted to be removably coupled to the electrical appliance. In the present embodiment, the base member 304 may include a first half portion 310 and a second half portion 312. The first half portion 310 may be integral to the bottom end portion 308 of the body member 302, and the second half portion 312 may be adapted to be removably coupled to the first half portion 310. Further, the first half portion 310 and the second half portion 312 are capable of receiving a portion of the electrical appliance therebetween, and thereafter may be coupled to each other by an attaching mechanism for enabling the mounting of the support component 300 on the electrical appliance.

In the present embodiment, the support component 300 may also include an attaching mechanism having a plurality of eyelets configured on the first half portion 310 and the second half portion 312. For example, the attaching mechanism may include a plurality of eyelets 314 configured on the first half portion 310, and a plurality of eyelets 316 configured on the second half portion 312. The attaching mechanism may further include a plurality of nut and bolt arrangements capable of removably coupling the first half portion 310 and the second half portion 312. For example, the attaching mechanism may include a plurality of bolts 318 and a plurality of nuts 320. The plurality of bolts 318 may be received through the plurality of eyelets 314 and 316 respectively. Thereafter, the plurality of bolts 318 may be coupled to the plurality of nuts 320 for removably coupling the first half portion 310 and the second half portion 312, securing a portion of the electrical appliance therebetween. Accordingly, the base member 304 of the support component 300 may be capable of being removably coupled to the portion of the electrical appliance.

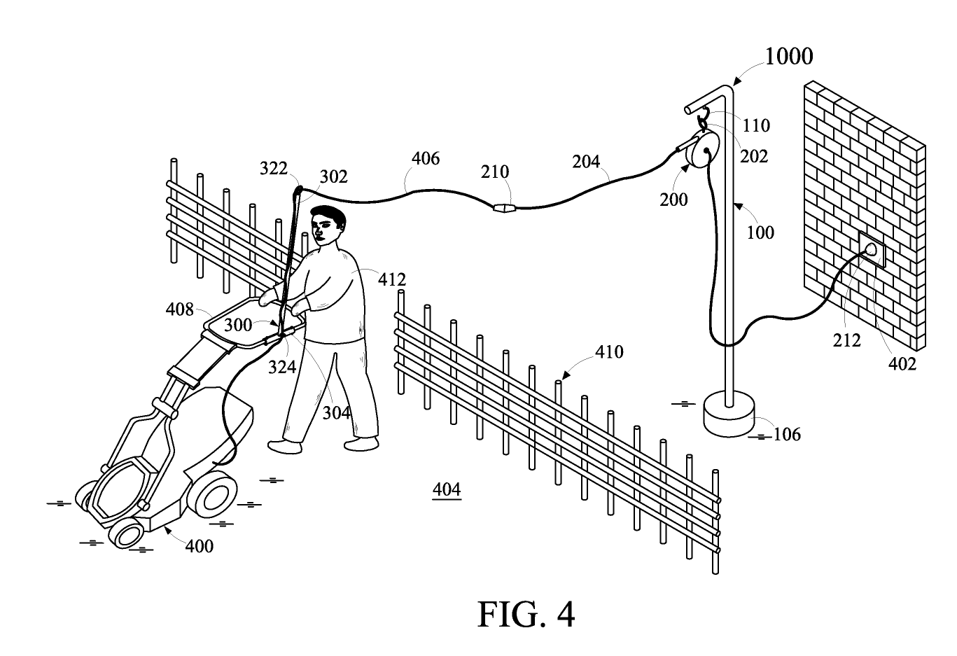

The support component 300 may further include a pair of loop members 322 and 324 configured on the body member 302. More specifically, the loop member 322 may be configured on the top end portion 306 of the body member 302 and the loop member 324 may be configured on the bottom end portion 308 of the body member 302. The pair of loop members 322 and 324 may receive the power cord of the electrical appliance and or a portion of the extension cord 204 therethrough, when the power cord is coupled to the extension cord 204, as shown in FIG. 4, for supporting the power cord of the electrical appliance.

Referring to FIG. 4, an environment in which the extension cord assembly 1000 of FIG. 1 may be used in conjunction with an electrical appliance. More specifically, FIG. 4 shows the extension cord assembly 1000 that may be used in conjunction with a lawn mower 400, for performing yard work. For example, the extension cord assembly 1000 may be used in conjunction with the lawn mower 400, for trimming grasses on a yard area, when a power source is distantly located form the lawn mower 400. The term “power source” used herein may be a wall outlet 402 capable of providing electrical power to the lawn mower 400 for the operation thereof.

As shown in FIG. 4, the support structure 100 of the extension cord assembly 1000 may rest on a ground surface 404. More specifically, the weighted base 106 of the support structure 100 may be rested on the ground surface 404 for erecting the support structure 100 in a vertically upward position. However, for the support structure 100 with the plurality of spikes 108 (as shown in FIG. 2), the plurality of spikes 108 may be driven into the ground surface 404 for erecting the support structure 100 in a vertically upward position.

Further, the extension cord housing 200 may be carried by the support structure 100 using the hook 110, configured on the support structure 100, and the loop 202, configured on the extension cord housing 200. Furthermore, the extension cord 204 may be pulled out of the extension cord housing 200 for electrically coupling the lawn mower 400 with the wall outlet 402. More specifically, the male connector 212 of the extension cord 204 may be electrically coupled to the wall outlet 402, and the female connector 210 of the extension cord 204 may be electrically coupled to a power cord 406 of the lawn mower 400.

The power cord 406 may be supported by the support component 300. Specifically, the power cord 406 may be received by the pair of loop members 322 and 324 of the support component 300 for being supported, when the power cord 406 is electrically coupled to the extension cord 204. Further, as explained herein, in conjunction with FIG. 3, the support component 300 may be adapted to be removably coupled to a portion of an electrical appliance. More specifically, the base member 304 of the support component 300 may be coupled to a handle 408 of the lawn mower 400, as shown in FIG. 4. Accordingly, the support component 300 is capable of supporting the power cord 406, electrically coupled to the extension cord 204.

As shown in FIG. 4, the extension cord 204 may be held above and away from the ground surface 404 and thereby avoiding a contact between the extension cord 204 and articles, such as fencing 410, resting on the ground surface 404. Accordingly, the extension cord 204 may be used uninterruptedly while using the lawn mower 400 for performing yard work. More specifically, upon holding the extension cord 204 away from the ground surface 404, the possibility of the extension cord 204 getting tangled up with the articles on the ground surface 404 may be avoided. Therefore, an individual 412 may easily handle and operate the lawn mower 400 without investing any time, which would have been required for untangling the extension cord 204.

Additionally, problems such as, an extension cord getting severed by blades of the lawn mower 400 or an extension cord getting caught up in the blades of the lawn mower 400 may be also avoided with the use of extension cord assembly 1000 of the present disclosure. Similarly, instead of the lawn mower 400 other electrical appliances, such as a weed whacker, a leaf blower, and a hedge trimmer, may be used in conjunction with the extension cord assembly 1000 for while performing outside work.

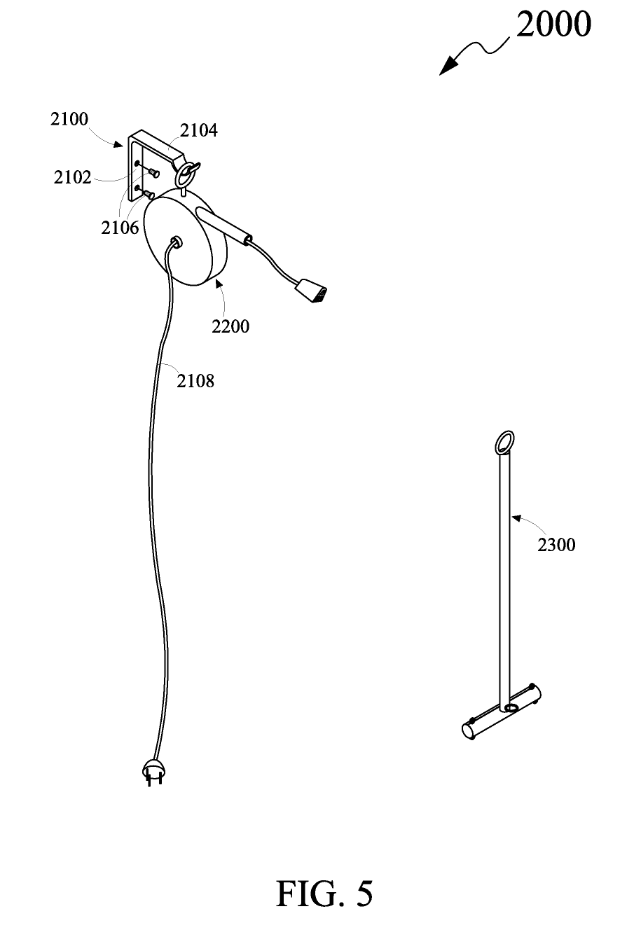

Referring now to FIG. 5, a perspective view of another embodiment of an extension cord assembly 2000 is shown. The extension cord assembly 2000 may include a support structure 2100, an extension cord housing 2200, and a support component 2300. The extension cord housing 2200 and the support component 2300 of the extension cord assembly 2000 are structurally and functionally similar to the extension cord housing 200 and the support component 300 of the extension cord assembly 1000; accordingly, description thereof is let go for the sake of brevity.

The support structure 2100 of the extension cord assembly 2000 may be a bracket. Further, the support structure 2100 may include a plate portion 2102 and a hook portion 2104 integral to the plate portion 2102. The plate portion 2102 of the support structure 2100 may be rested on a surface. For example, in the present embodiment, the extension cord assembly 2000 may include fasteners, such as screws 2106, capable of mounting the plate portion 2102 of the support structure 2100 on a surface. The term “surface” used herein may be referred to as an elevated surface, on which the support structure 2100 may be mounted. For example, the surface may include a surface of a wall or a surface of a tree, on which the support structure 2100 may be mounted for holding the extension cord housing 2200 away for a ground surface.

More specifically, in the present embodiment, the extension cord housing 2200 may be carried by the hook portion 2104 of the support structure 2100. Accordingly, an extension cord, such as an extension cord 2108, may be retractably released from the extension cord housing 2200 and held away from the ground surface for avoiding a contact between the extension cord 2108 and articles resting on the ground surface. Therefore, the extension cord assembly 2000 may provide an uninterrupted use of the extension cord 2108, when used in conjunction with a distantly located electrical appliance, such as the lawn mower 400 (See FIG. 4).

Based on the foregoing description of the present disclosure, the extension cord assemblies 1000 and 2000 may be used in conjunction with electrical appliances that may be distantly located from a power source, such as a wall outlet. The extension cord assemblies 1000 and 2000 of the present disclosure promote a convenient and efficient use of an electrical appliance, such as a lawn mower and a snow blower, which may be generally used for performing outdoor activities. Specifically, the extension cord assemblies 1000 and 2000 may be capable of holding extension cords 204 and 2108 respectively, away from a ground surface and thereby avoiding tangling of the extension cords 204 and 2108 with articles resting on the ground surface. Accordingly, an individual may conveniently and efficiently use the electrical appliance without investing any time, which would have been required for untangling the extension cords 204 and 2108.

The foregoing descriptions of specific embodiments of the present disclosure have been presented for purposes of illustration and description. They are not intended to be exhaustive or to limit the present disclosure to the precise forms disclosed, and obviously many modifications and variations are possible in light of the above teaching. The embodiments were chosen and described in order to best explain the principles of the present disclosure and its practical application, to thereby enabling others skilled in the art to best utilize the present disclosure and various embodiments with various modifications as are suited to the particular use contemplated. It is understood that various omission and substitutions of equivalents are contemplated as circumstance may suggest or render expedient, but such are intended to cover the application or implementation without departing from the spirit or scope of the claims of the present disclosure.

What is claimed is:

1. An extension cord assembly for an electrical appliance, the extension cord assembly comprising:
a support structure adapted to be rested on a surface;
an extension cord housing adapted to be carried by the support structure; the extension cord housing configured to retractably releasing an extension cord capable of electrically coupling the electrical appliance to a power source, and
wherein the extension cord is positioned away from a ground surface for avoiding a contact between the extension cord and articles resting on the ground surface and thereby enabling uninterrupted use of the extension cord.

2. The extension cord assembly of claim 1 further comprising a support component adapted to be mounted on the electrical appliance, the support component capable of supporting a power cord of the electrical appliance when the power cord is electrically coupled to the extension cord.

3. The extension cord assembly of claim 2, wherein the support component comprises
a body member having an upper end and an opposing lower end;
a base member configured at the lower end of the body member, the base member adapted to be removably coupled to a portion of the electrical appliance; the body member further comprising a loop member at each of the ends thereof; and
the loop members are capable of receiving the power cord therethrough for supporting the power cord when electrically coupled to the extension cord.

4. The extension cord assembly of claim 3, wherein the base member comprises
a first half portion integral to the lower end of the body member, and
a second half portion adapted to be removably coupled to the first half portion securing the portion of electrical appliance therebetween.

5. The extension cord assembly of claim 1, wherein the support structure comprises an upper end portion and a lower end portion, the lower end portion of the support structure is adapted to be rested on the ground surface.

6. The extension cord assembly of claim 5, wherein the support structure comprises a hook configured at the upper end portion, the hook is adapted in carrying the extension cord housing near the upper end portion.

7. The extension cord assembly of claim 5, wherein the support structure comprises a weighted base configured at the lower end portion, the weighted base is adapted to be placed on the ground surface for allowing the support structure to rest on the ground surface.

8. The extension cord assembly of claim 5, wherein the support structure comprises a plurality of spikes configured at the lower end portion, the plurality of spikes is adapted to be driven into the ground surface for allowing the support structure to rest on the ground surface.

9. The extension cord assembly of claim 5, wherein the support structure is a pole.

10. The extension cord assembly of claim 1, wherein the support structure comprises a plate portion adapted to be rested on a surface and a hook portion integral to the plate portion, the hook portion capable of carrying the extension cord housing.

11. The extension cord assembly of claim 10, wherein the support structure is a bracket.

12. The extension cord assembly of claim 1, wherein the support structure is made of a metal material.

13. The extension cord assembly of claim 1, wherein the support structure is made of a sturdy plastic material.

14. The extension cord assembly of claim 2, wherein the support component is made of a metal material.

15. The extension cord assembly of claim 2, wherein the support component is made of a sturdy plastic material.
